(19) United States
(12) Patent Application Publication
(10) Pub. No.: US 2006/0062336 A1
(43) Pub. Date: Mar. 23, 2006

(54) Method of channel estimation

(75) Inventors: Zing-Wei Kang, Taipei City (TW); Sheng-Jie Chen, TaoYuan Hsien (TW)

Correspondence Address: LADAS & PARRY, 26 WEST 61ST STREET, NEW YORK, NY, 10023, US

(73) Assignee: BENQ CORPORATION

(21) Appl. No.: 11/179,915

(22) Filed: Jul. 12, 2005

(30) Foreign Application Priority Data
Sep. 17, 2004 (TW) 93128317

(51) Int. Cl. H03D 1/04; H03H 7/30

(52) U.S. Cl. 375/346; 375/229

(57) ABSTRACT

A method for channel estimation is provided. Firstly is to estimate channel impulse response (CIR) of training sequence. Next is to generate a soft data by means of an equalizer according to the CIR of the training sequence. Subsequently is to estimate CIRs of data sequences according to the interposed training sequence by correlation channel estimation. Next is to define a weight by means of auto-correlation of the estimated data sequence and then to cancel the interference of channel by the weight. Finally is to use the soft data and the non-interference CIR to find out the data stored in the data sequence.

### BACKGROUND OF THE INVENTION

(1) Field of the Invention

The invention relates to a method of channel estimation, and more particularly to utilize the data in the transmitted data sequence to accomplish channel estimation.

(2) Description of the Prior Art

FIG. 1 illustrates the basic framework of wireless communication system. The communication system at least includes a transmitter 12 and a receiver 14. Each of the transmitter 12 and receiver 14 has its antenna 16 and 18 for transmitting/receiving signals and then after a number of signal processing steps (such as demodulation, decoding, etc.) so as to get useful data. In the process from transmitter 12 to receiver 14, signals are propagated in channel 20. Ideally, the signal received from the receiver 14 should match the signal transmitted from the transmitter 12.

Actually, the received signals will be affected by refraction or reflection with various objects over the channel 20 or with the relative position changing by transmitter and receiver during the signal transmission. Therefore, the following phenomena might occur in channel 20 such as multi-path delay, fading, interference, etc. and further conclude signal distortion. Especially for mobile communication system, the relative position of transmitter and receiver are changing frequently that with different speed of moving receiver (or transmitter) results in different level of Doppler spread and causes more seriously distortion problem.

Actually, the received signals will be affected by refraction or reflection with various objects over the channel 20 or with the relative position changing by transmitter and receiver during the signal transmission. Therefore, the following phenomena might occurre in channel 20 such as multi-path delay, fading, interference, etc. and further conclude signal distortion. Especially for mobile communication system, the relative position of transmitter and receiver might be changing frequently that with different speed of moving receiver (or transmitter) results in different level of Doppler spread and causes more seriously distortion problem.

In order to simulate signals in channel transmission, some channel estimation method are adopted to adjust signals being affected in channel so as to compensate the affected signal. Accordingly, channel estimation plays an important rule in wireless communication system (e.g. GSM). However, in linear time variant channel, channel responses vary with time that channel estimation becomes more important in multi-path time variant channel. Traditionally, linear least square method is used for estimating channel impulse response (CIR) in channel estimation. But, it is too complicate to calculate the operator of inverse matrix for linear least square method. The other channel estimation uses adaptive algorithm named as Adaptive Channel Estimation, but this method have a problem that is converge time. And the step size is difficult to choose in the different Doppler frequency (speed of vehicle).

Otherwise, another approach to estimate data is to interpose training sequence (TS) between data sequences in transmission signal, and because of TS is the known data that we can estimate CIR by correlation channel estimation so as to obtain data in transmission signal. However, the drawback of foregoing approach is suitable for stable signals. If the channel is with high noise interference or in the condition of high speed moving vehicle that CIR estimated from training sequence can not express for the CIR of transmission data and distortion of data may be generated.

Therefore, in order to improve the foregoing disadvantages, the present invention provides a channel estimation method to eliminate interference in channel and reduce complex calculation.

### SUMMARY OF THE INVENTION

Accordingly, it is the main object of the present invention to provide a channel estimation method by utilizing the estimated CIR of data sequence within data burst so as to obtain data in the data burst.

The present invention provides a channel estimation method in a receiver for receiving signals to estimate channel impulse response (CIR) of received signal, the receiver comprised a equalizer (e.g. Viterbi equalizer) for decode data within the signal, the signal comprised a plurality of data bursts, any of the data burst comprises two data sequences (DSs) and a training sequence (TS) interposed between the two DSs, the channel estimation method comprises the following steps. Firstly is to estimate CIR of the TS. Next step is to generate a soft data by means of said equalizer according to the CIR of the TS. Subsequently is to estimate CIRs of the DSs which are adjacent to the TS by correlation channel estimation.

The next step is to define a weight according to auto-correlation of the DS. Then, using the weight to cancel interference of the channel and obtaining a interference free CIR. Finally is to utilize the soft data and the interference free CIR to obtain data in the data sequence.

### BRIEF DESCRIPTION OF THE DRAWINGS

The present invention will now be specified with reference to its preferred embodiment illustrated in the drawings, in which

FIG. 1 is a schematic view of basic framework for wireless communication system;

FIG. 2 is a flow chart of receiving data in a receiver in accordance with one embodiment with the present invention;

FIG. 3 is a schematic view of composition of data burst transmitted in wireless communication system; and

FIG. 4 is a function block about estimating data in a receiver.

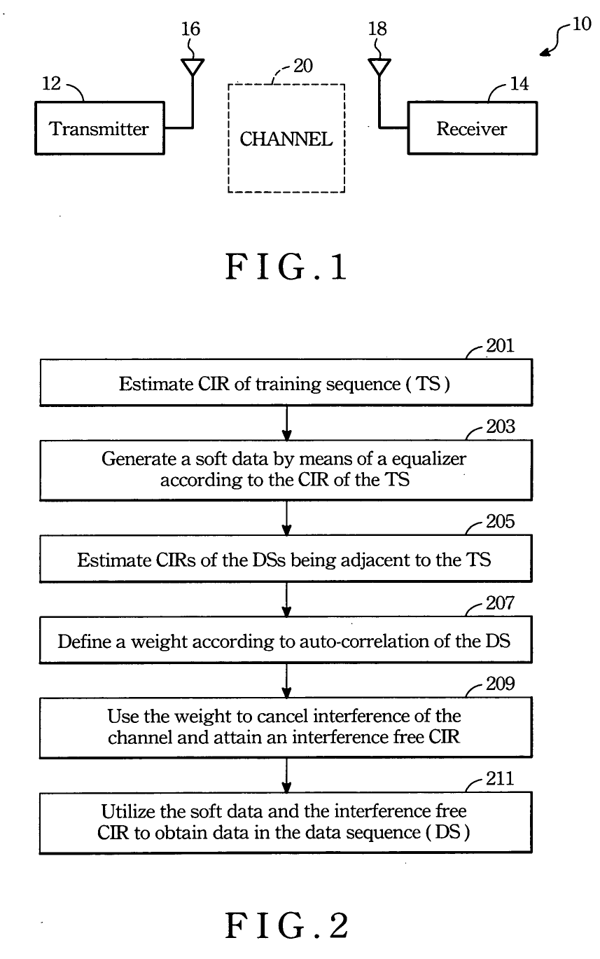

### DESCRIPTION OF THE PREFERRED EMBODIMENT

The invention disclosed herein is to a method of channel estimation, and more particularly to utilize the data in the transmitted data sequence to accomplish channel estimation. The invention provides a basic concept of minimum mean square error interference cancellation so as to utilize the cancellation method to reduce interference. Firstly, we adopt a correlation method to get channel impulse response (CIR) of the data sequence. Due to the data sequence is not a well pseudo-noise sequence that we use the minimum mean square error interference cancellation method to cancel the interference of CIR occurred by other paths beyond the main path CIR. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

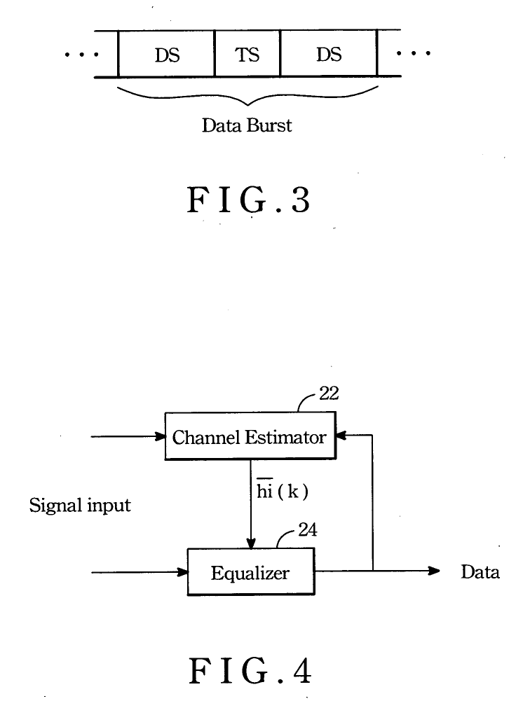

FIG. 2 illustrates a flow chart of receiving data in a receiver in accordance with one embodiment with the present invention. Firstly is to estimate CIR of training sequence (TS) in accordance with step 201. Also referring FIG. 3, depicting a schematic view of composition of data burst transmitted in wireless communication system. There is only one data burst in the drawing. The data burst may include two data sequences (DSs) and one training sequence (TS) where TS (may include 26 bits data) is interposed between the two DSs and contains a known data recognizing by the receiver and transmitter. The DSs could include 58 bits audio, video or audio/video data separately. Due to the characteristic of data sequence is not as of training sequence and the non-zero lag of correlation value for data sequence is not zero that interference maybe occurred by those correlation values when we use the data sequence as fundamental basis for channel estimation in the following steps.

Subsequently, in step 203, we generate a soft data by means of a equalizer according to CIR of the TS. In the preferred embodiment of the present invention, the equalizer may adopt in a viterbi algorithm for decoding data. The soft data can be a probability for determine the received data is right or not. It should be noted that the foregoing soft data maybe used as a basis to determine interference cancellation in the following steps. For example, except for the value of “1” or “0”, the output of the soft data also express the probability for appearing “1” and “0”, such as [“1”, 0.99], [“0”, 0.01] denoting the probability is 0.99 as data will be “1”, and the probability is 0.01 as data will be “0” separately. Then the data coming from the equalizer will be “1”. Otherwise, if the output of the soft data are [“1”, 0.55] and [“0”, 0.45] that express the received signal is in the condition with serious noise or in an unstable channel.

The next step 205 is to estimate CIRs of the DSs which are adjacent to the TS. In the preferred embodiment of the present invention, the estimated CIR of the TS can be written as follow:

$${\tilde{h}}_{n} ( k ) = {\sum }_{l = 0}^{L - 1} {c}_{n , l} ( k ) {h}_{l} ( k ) + {n}_{n} ( k ) , \qquad ( 1 )$$

where c_{n,l}(k) denotes correlation of received data and estimated data a time k, hₗ(k) denotes real channel impulse response (CIR), and nₙ(k) denotes noise.

Accordingly, in step 207, to define a weight according to auto-correlation of the data sequence (DS). In the preferred embodiment of the present invention, the weight can be calculated by the following equation:

$${w}_{i , j} ( k ) = \frac{{\overline{c}}_{i , j} ( k ) {ρ}_{i}}{{ρ}_{i} + {\tilde{σ}}_{i}} , \qquad ( 2 )$$

where w_{i,j} denotes the weight of the interference tap at jth in ith channel path, \overline{c}_{i,j}(k) denotes auto-correlation of estimated data, ρᵢ denotes magnitude of channel power at ith delay path, and \tilde{σ}ᵢ denotes magnitude of noise power at ith delay path. And the following descriptions will illustrate how to get equation (2).

First of all, in order to get interference free CIR that we have to find out the minimum square error ε between ideal CIR and estimated CIR. In other words, we can find the optimum weight to let square error minimum. Therefore, the minimum square error of hᵢ(k) and \overline{h}ᵢ(k) can be calculated as follow:

$${h}_{io} ( k ) = arg {min}_{{\overline{h}}_{i} ( k )} E [ {\vert {h}_{i} ( k ) - {\overline{h}}_{i} ( k ) \vert}^{2} ] \qquad ( 3 )$$

Besides, we assumed that CIR after interference is canceled can be written as follow:

$${\overline{h}}_{i} ( k ) = {\tilde{h}}_{i} ( k ) - {\sum }_{{j = 0}_{j \neq i }}^{L - 1} {w}_{i , j} {\tilde{h}}_{j} ( k ) \qquad ( 4 )$$

Hence, we use equation (3) to obtain the minimum square error ε. The minimum square error can be a function of weight w_{i,j}(k) that let

$$\frac{\partial ɛ ( k )}{\partial {w}_{i , j} ( k )} = 0$$

so as to get optimum weight of the minimum square error. Then take ε to minimum square error.

$$\begin{matrix}ɛ = E [ {\vert {h}_{i} ( k ) - {\overline{h}}_{i} ( k ) \vert}^{2} ] \\ = E [ ( {h}_{i} ( k ) - {\overline{h}}_{i} ( k ) ) \times {( {h}_{i} ( k ) - {\overline{h}}_{i} ( k ) )}^{*} ] \\ = E [ {h}_{i} ( k ) {h}_{i}^{*} ( k ) - {\overline{h}}_{i} ( k ) {h}_{i}^{*} ( k ) - {h}_{i} ( k ) {\overline{h}}_{i}^{*} ( k ) - {\overline{h}}_{i} ( k ) {\overline{h}}_{i}^{*} ( k ) ] \\ = E [ {h}_{i} ( k ) {h}_{i}^{*} ( k ) ] - E [ {\overline{h}}_{i} ( k ) {h}_{i}^{*} ( k ) ] - E [ {h}_{i} ( k ) {\overline{h}}_{i}^{*} ( k ) ] + E [ {\overline{h}}_{i} ( k ) {\overline{h}}_{i}^{*} ( k ) ]\end{matrix} \qquad ( 5 )$$

Before use partial differential with equation (5), we calculate E[hᵢ(k)hᵢ*(k)┘, E[\overline{h}ᵢ(k)hᵢ*(k)┘, E[hᵢ(k)\overline{h}ᵢ*(k)┘, and E[\overline{h}ᵢ(k)\overline{h}ᵢ*(k)┘ first, where

$$\begin{matrix}E [ {\overline{h}}_{i} ( k ) {h}_{i}^{*} ( k ) ⌋ = E [ {h}_{i} ( k ) {\overline{h}}_{i}^{*} ( k ) ⌋ and E [ {h}_{i} ( k ) {h}_{i}^{*} ( k ) ⌋ = {σ}_{i} , furthermore , \\ \begin{matrix}E [ {\overline{h}}_{i} ( k ) {h}_{i}^{*} ( k ) ] = E [ ( {\tilde{h}}_{i} ( k ) - {\sum }_{{j = 0}_{j \neq i }}^{L - 1} {w}_{i , j} {\tilde{h}}_{j} ( k ) ) {h}_{i}^{*} ( k ) ] \\ = E [ {\tilde{h}}_{i} ( k ) {h}_{i}^{*} ( k ) ] - {\sum }_{{j = 0}_{j \neq i }}^{L - 1} {w}_{i , j} E [ {\tilde{h}}_{j} ( k ) {h}_{i}^{*} ( k ) ] \\ = {ρ}_{i} - {\sum }_{{j = 0}_{j \neq 1}}^{L - 1} {w}_{i , j} {\overline{c}}_{j , i} ( k ) {ρ}_{i}\end{matrix} & ( 5.1 ) \\ \begin{matrix}E [ {\tilde{h}}_{j} ( k ) {h}_{i}^{*} ( k ) ] = E [ ( {\sum }_{l = 0}^{L - 1} {c}_{j , l} ( k ) {h}_{l} ( k ) + {n}_{j} ( k ) ) {h}_{i}^{*} ( k ) ] \\ = E [ {c}_{j , i} ( k ) ] E [ {h}_{i} ( k ) {h}_{i}^{*} ( k ) ] \\ = {\overline{c}}_{j , i} ( k ) {ρ}_{i}\end{matrix} & ( 5.2 ) \\ \begin{matrix}E [ {\overline{h}}_{i} ( k ) {\overline{h}}_{i}^{*} ( k ) ] = E [ ( {\tilde{h}}_{i} ( k ) - {\sum }_{{s = 0}_{s \neq i }}^{L - 1} {w}_{i , s} {\tilde{h}}_{s} ( k ) ) {( {\tilde{h}}_{i} ( k ) - {\sum }_{{r = 0}_{r \neq i }}^{L - 1} {w}_{i , r} {\tilde{h}}_{r} ( k ) )}^{*} ] \\ = E [ {\tilde{h}}_{i} ( k ) {\tilde{h}}_{i}^{*} ( k ) ] - E [ {\tilde{h}}_{i}^{*} ( k ) ( {\sum }_{{s = 0}_{s \neq i }}^{L - 1} {w}_{i , s} {\tilde{h}}_{s} ( k ) ) ] - E [ {\tilde{h}}_{i} ( k ) {( {\sum }_{{r = 0}_{r \neq i }}^{L - 1} {w}_{i , r} {\tilde{h}}_{r} ( k ) )}^{*} ] \\ + E [ ( {\sum }_{{s = 0}_{s \neq i }}^{L - 1} {w}_{i , s} {\tilde{h}}_{s} ( k ) ) {( {\sum }_{{r = 0}_{r \neq i }}^{L - 1} {w}_{i , r} {\tilde{h}}_{r} ( k ) )}^{*} ] \\ = E [ {\tilde{h}}_{i} ( k ) {\tilde{h}}_{i}^{*} ( k ) ] - {\sum }_{{s = 0}_{s \neq i }}^{L - 1} {w}_{i , s} E [ {\tilde{h}}_{i} ( k ) {\tilde{h}}_{s}^{*} ( k ) ] - {\sum }_{{r = 0}_{r \neq i }}^{L - 1} {w}_{i , r} E [ {\tilde{h}}_{i} ( k ) {\tilde{h}}_{r}^{*} ( k ) ] \\ + ( {\sum }_{{s = 0}_{s \neq i }}^{L - 1} {\sum }_{{r = 0}_{r \neq i }}^{L - 1} {w}_{i , s} E [ {\tilde{h}}_{r} ( k ) {\tilde{h}}_{s}^{*} ( k ) ] {w}_{r , i} ) \\ = \{ {\sum }_{i = 0}^{L - 1} {c}_{i , i}^{2} ( k ) {ρ}_{i} + {σ}_{i} \} - {\sum }_{{s = 0}_{s \neq i }}^{L - 1} {w}_{i , s} {Co}_{i , s} ( k ) - {\sum }_{{r = 0}_{r \neq i }}^{L - 1} {w}_{i , r} {Co}_{i , r} ( k ) \\ + ( {\sum }_{{s = 0}_{s \neq i }}^{L - 1} {\sum }_{{r = 0}_{r \neq i }}^{L - 1} {w}_{i , s} {Co}_{s , r} ( k ) {w}_{r , i} ) \\ \end{matrix} & ( 5.3 ) \\ \begin{matrix}E [ {\tilde{h}}_{i} ( k ) {\tilde{h}}_{j}^{*} ( k ) ] = E [ ( {\sum }_{p = 0}^{L - 1} {c}_{i , p} {h}_{p} ( k ) + {n}_{i} ) {( {\sum }_{q = 0}^{L - 1} {c}_{j , q} {h}_{q} ( k ) + {n}_{j} )}^{*} ] & & & \\ = {\sum }_{p = 0}^{L - 1} {\overline{c}}_{i , p} ( k ) {ρ}_{p} {\overline{c}}_{p , j} ( k ) = {Co}_{i , j} ( k ) & i \neq j & & \\ = {\sum }_{p = 0}^{L - 1} {\overline{c}}_{i , p}^{2} ( k ) {ρ}_{p} + {σ}_{i} & & & i = j\end{matrix} & ( 5.4 ) \\ \begin{matrix} {\overline{c}}_{i , j} ( k ) = E [ {c}_{i , j} ( k ) ] \\ = \frac{1}{N} {\sum }_{n = k}^{k - N + 1} E [ {a}_{n + i} {a}_{n + j} ] = \frac{1}{N} {\sum }_{n = k}^{k - N + 1} E [ {a}_{n + i} {a}_{n + j} ] \\ = \{ \begin{matrix}\frac{1}{N} {\sum }_{n = k}^{k - N + 1} ( 2 p ( {a}_{n + i} \vert r ) - 1 ) ( 2 p ( {a}_{n + j} \vert r ) - 1 ) & for i \neq j \\ 1 & for i = j\end{matrix}\end{matrix} & ( 5.5 )\end{matrix}$$

To substitute (5.1)˜(5.5) into equation (5), then partial differential function ε and set zero after partial differential. We can find optimum value for ω_{i,j} as follow:

$$\frac{\partial ɛ}{\partial {w}_{i , j}} = - 2 {\overline{c}}_{i , j} ( k ) {ρ}_{i} - 2 {Co}_{i , j} ( k ) + 2 {\sum }_{{r = 0}_{r \neq i }}^{L - 1} {Co}_{j , r} ( k ) {w}_{i , r} = 0 \qquad ( 6 )$$

Hence, the optimum weight at time k according to equation (6) can be written as follow:

$${w}_{i , j} ( k ) = \frac{{\overline{c}}_{i , j} ( k ) {ρ}_{i} + {Co}_{i , j} ( k ) - {\sum }_{{r = 0}_{ r \neq i , j }}^{L - 1} {Co}_{j , r} ( k ) {w}_{i , r} ( k )}{{Co}_{j , j} ( k )} \qquad ( 7 )$$

When i≠j, the Co_{i,j}≈0. Without of loss generality, we can reduce the equation (7) as:

$${w}_{i , j} ( k ) = \frac{{\overline{c}}_{i , j} ( k ) {ρ}_{i}}{{Co}_{j , j} ( k )} = \frac{{\overline{c}}_{i , j} ( k ) {ρ}_{i}}{{\sum }_{p = 0}^{L - 1} {\overline{c}}_{i , p}^{2} ( k ) {ρ}_{p} + {σ}_{i}} = \frac{{\overline{c}}_{i , j} ( k ) {ρ}_{i}}{{\overline{c}}_{i , i}^{2} ( k ) {ρ}_{i} {\sum }_{{p = 0}_{p \neq i }}^{L - 1} {\overline{c}}_{i , p}^{2} ( k ) {ρ}_{p} + {σ}_{i}} = \frac{{\overline{c}}_{i , j} ( k ) {ρ}_{i}}{{ρ}_{i} + {\tilde{σ}}_{i}} ,$$

where \overline{c}_{i,j}(k) denotes auto-correlation of estimated data, ρᵢ denotes magnitude of channel power at ith delay path, and \tilde{σ}ᵢ denotes magnitude of noise power at ith delay path.

Referring back to FIG. 2, in step 209, to use the weight obtained from step 207 to cancel interference of channel so as to obtain a interference free CIR as shown in equation (4). Finally, utilizing the soft data (obtained from step 203) and the interference free CIR (obtained from step 209) to obtain data in the data sequence. FIG. 4 illustrates a function block about estimating data in a receiver. When the receiver received signal from antenna (not shown in the drawing), use the method of present invention to input the CIR (after proceeding the step of interference cancellation), \overline{h}ᵢ(k), to the equalizer 24 through the channel estimator 22, meanwhile, feedback the soft data generated from equalizer 24 to channel estimator 22 so as to obtain the precise CIR \overline{h}ᵢ(k). Therefore, by means of the channel estimation method of the present invention that can obtain data at every data burst in transmitted signals sequentially.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

I claim:

1. A method of channel estimation in a receiver for receiving signals to estimate channel impulse response (CIR) of received signal, the receiver comprised a equalizer to decode data within the signal, the signal comprised a plurality of data bursts, any of the data burst having two data sequences (DSs) and a training sequence (TS) interposed between the two DSs, the channel estimation method comprises the steps of:
(a) estimating CIR of the TS;
(b) generating a soft data by means of said equalizer according to the CIR of the TS;
(c) estimating CIRs of the DSs which are adjacent to the TS by correlation channel estimation;
(d) defining a weight according to auto-correlation of the DS;
(e) using the weight to cancel interference of channel and obtaining a interference free CIR; and
(f) utilizing the soft data and the interference free CIR to obtain data in the data sequence.

2. The channel estimation method according to claim 1, wherein the step (c) is calculated by the following equation:
$${\tilde{h}}_{n} ( k ) = {\sum }_{l = 0}^{L - 1} {c}_{n , l} ( k ) {h}_{l} ( k ) + {n}_{n} ( k ) ,$$
where c_{n,l}(k) denotes correlation of received data and estimated data at time k, hₗ(k) denotes real channel impulse response (CIR), and nₙ(k) denotes noise.

3. The channel estimation method according to claim 1, wherein the step (d) is calculated by the following equation:
$${w}_{i , j} ( k ) = \frac{{\overline{c}}_{i , j} ( k ) {ρ}_{i}}{{ρ}_{i} + {\tilde{σ}}_{i}} ,$$
where \overline{c}_{i,j}(k) denotes auto-correlation of estimated data, ρᵢ denotes magnitude of channel power at ith delay path, and \tilde{σ}ᵢ denotes magnitude of noise power at ith delay path.

4. The channel estimation method according to claim 1, wherein the interference free CIR(\overline{h}ᵢ(k)) is calculated by the following equation:
$${\overline{h}}_{i} ( k ) = {\tilde{h}}_{i} ( k ) - {{\sum }_{j = 0}^{L - 1}}_{j \neq i} {w}_{i , j} ( k ) {\tilde{h}}_{j} ( k ) .$$

5. The channel estimation method according to claim 1, wherein the data sequence in the data burst contains 58 bits data.

6. The channel estimation method according to claim 1, wherein the training sequence in the data burst contains 26 bits data.

7. The channel estimation method according to claim 1, wherein the channel estimation method is applied in GPRS system.

8. The channel estimation method according to claim 1, wherein the channel estimation method is applied in GSM system.

9. The channel estimation method according to claim 1, wherein data in the data burst belongs to audio data.

10. The channel estimation method according to claim 1, wherein data in the data burst belongs to video data.

11. The channel estimation method according to claim 1, wherein data in the data burst belongs to audio and video data.

12. A method of channel estimation in a receiver for receiving signals to estimate channel impulse response (CIR) of received signal, the receiver comprised a equalizer so as to decode data within the signal, the signal comprised a plurality of data burst, any of the data burst comprises two data sequences (DSs) and a training sequence (TS) interposed between the two DSs, the channel estimation method comprises the steps of:
(a) estimating CIRs of the DSs which are adjacent to the TS by correlation channel estimation;
(b) defining a weight according to auto-correlation of the DS; and
(c) using the weight to cancel interference of channel and obtaining a interference free CIR.

13. The channel estimation method according to claim 12, further comprising:
(d) estimating CIR of the TS;
(e) generating a soft data by means of said equalizer according to the CIR of the TS; and
(f) utilizing the soft data and the interference free CIR to obtain data in the data sequence.

14. The channel estimation method according to claim 12, wherein the step (a) is calculated by the following equation:
$${\tilde{h}}_{n} ( k ) = {\sum }_{l = 0}^{L - 1} {c}_{n , l} ( k ) {h}_{l} ( k ) + {n}_{n} ( k ) ,$$
where c_{n,l}(k) denotes correlation of received data and estimated data at time k, hₗ(k) denotes real channel impulse response (CIR), and nₙ(k) denotes noise.

15. The channel estimation method according to claim 12, wherein the step (b) is calculated by the following equation:
$${w}_{i , j} ( k ) = \frac{{\overline{c}}_{i , j} ( k ) {ρ}_{i}}{{ρ}_{i} + {\tilde{σ}}_{i}} ,$$
where \overline{c}_{i,j}(k) denotes auto-correlation of estimated data, ρᵢ denotes magnitude of channel power at ith delay path, and \tilde{σ}ᵢ denotes magnitude of noise power at ith delay path.

16. The channel estimation method according to claim 12, wherein the interference free CIR (\overline{h}ᵢ(k)) is calculated by the following equation:
$${\overline{h}}_{i} ( k ) = {\tilde{h}}_{i} ( k ) - {{\sum }_{j = 0}^{L - 1}}_{j \neq i} {w}_{i , j} ( k ) {\tilde{h}}_{j} ( k ) .$$

17. The channel estimation method according to claim 12, wherein the data sequence in the data burst contains 58 bits data.

18. The channel estimation method according to claim 1, wherein the training sequence in the data burst contains 26 bits data.

19. The channel estimation method according to claim 12, wherein the channel estimation method is applied in GPRS or GSM system.

20. The channel estimation method according to claim 12, wherein data in the data burst is selected from the group consisting of audio, video, or audio and video data.
